(19) United States
(12) Patent Application Publication
(10) Pub. No.: US 2026/0173886 A1
(43) Pub. Date: Jun. 18, 2026

(54) SEMICONDUCTOR PACKAGE

(71) Applicant: NTRIUM Inc., Siheung-si (KR)

(72) Inventors: Se Young Jeong, Siheung-si (KR); Yoon Hyun Kim, Siheung-si (KR); Byoung Woong Moon, Siheung-si (KR); Do Hyun Kim, Siheung-si (KR); Cheol Woong Kim, Siheung-si (KR); Tae Hee Ku, Siheung-si (KR); Byung Sun Lee, Siheung-si (KR); Tae Hun Lee, Siheung-si (KR)

(73) Assignee: NTRIUM Inc., Siheung-si (KR)

(21) Appl. No.: 19/029,530

(22) Filed: Jan. 17, 2025

(30) Foreign Application Priority Data
Dec. 18, 2024 (KR) 10-2024-0190571

(51) Int. Cl. H01L 23/552; H01L 21/56; H01L 23/29; H01L 23/31; H01L 23/367; H01L 23/498

(52) U.S. Cl. CPC H10W 42/20; H10W 74/012; H10W 74/111; H10W 74/15; H10W 90/701; H10W 40/22; H10W 74/47

(57) ABSTRACT

A semiconductor package according to the present invention comprises a substrate having a ground pad, at least one electronic device electrically conductively attached to the substrate, an insulating portion encapsulating the electronic device; and an electromagnetic shielding layer conformally formed on the surface of the insulating portion, wherein the electromagnetic shielding layer is coated on the ground pad and electrically connected.

### CROSS-REFERENCE TO RELATED APPLICATIONS

This application claims the benefit of priority to Korean Patent Application No. KR 10-2024-0190571 (DAS code C589), titled “SEMICONDUCTOR PACKAGE,” filed by ENTRIUM Inc. on Dec. 18, 2024.

This application incorporates the entire contents of the foregoing application(s) herein by reference.

### TECHNICAL FIELD

The present invention relates to the technical field of semiconductor packages, and more particularly to technology for improving insulation and electromagnetic shielding performance of semiconductor packages.

### BACKGROUND ART

In conventional semiconductor packages, electromagnetic shielding was primarily achieved using metal shield cans. Shield cans play an important role in blocking EMI (Electromagnetic Interference) and RFI (Radio Frequency Interference) of semiconductor packages. This metal cover structure prevents interaction with external electromagnetic waves by covering the entire chip, while simultaneously providing thermal and mechanical stability to perform physical protection functions for the chip. However, due to the thickness and complex structure of metal shield cans, manufacturing costs increase, package lightweighting and miniaturization are limited, and individual EMI shielding effects of each component appear incomplete. As a result, this method is gradually showing limitations in the latest semiconductor packages.

In Prior Art Document 1, while protecting semiconductor chips using a metal shield can structure, there are problems of limited shielding performance and high manufacturing costs due to complex design. Additionally, due to the physical size of the shield can, there are difficulties in optimizing individual shielding performance for each device. As a result, the conventional shield can method is not suitable for modern semiconductor packages requiring miniaturization and weight reduction.

In Prior Art Document 2, EMI shielding coating technology that can replace shield cans has been proposed. This coating technology is a method to reduce EMI interference by applying materials with electromagnetic shielding capabilities to the package exterior. Unlike shield cans, this method contributes to reducing the overall package thickness and enables weight reduction. However, EMI shielding coating requires additional complex grounding processes with the substrate.
Prior Art Document 1: Korean Patent No. 10-1234567 “Semiconductor Package Structure Using Metal Shield Can”
Prior Art Document 2: U.S. Pat. No. 9,876,543 B2 “Semiconductor Package Manufacturing Method Applying EMI Shielding Coating”

### DISCLOSURE

### Technical Problem

The present invention aims to provide a semiconductor package that can improve shielding performance, achieve lightweighting and miniaturization, and reduce process difficulty for grounding while solving the aforementioned problems. Additionally, the present invention aims to provide a semiconductor package capable of rework.

### Technical Solution

According to one aspect of the present invention, a semiconductor package equipped with electromagnetic shielding comprises:
a substrate having a ground pad,
at least one electronic device that is electrically connected to the substrate,
an insulating portion encapsulating the electronic device,
an electromagnetic shielding layer conformally formed on the surface of the insulating portion,
wherein the electromagnetic shielding layer is coated on the ground pad and electrically connected.

Preferably, it includes a conductive dam means provided on the ground pad,
wherein the insulating portion and the electromagnetic shielding layer are electrically connected by contacting the dam means.

At this time, it includes an insulating dam means provided on the edge of the substrate,
wherein the electromagnetic shielding layer can be electrically connected by being formed on the insulating portion, the dam means, and the ground pad.

Preferably, the insulating portion is formed of a reworkable material.

At this time, the insulating portion can be formed of a UV-curable polymer material.

Preferably, the insulating portion is formed with a thickness of 10 μm to 200 μm.

At this time, the insulating portion can be formed by a conformal coating method.

Preferably, the conformal coating is performed using a material having a viscosity of 50-500 cPs (based on 25° C.).

Preferably, the electromagnetic shielding layer is formed with a thickness of 5 μm to 30 μm.

At this time, the electromagnetic shielding layer can be formed of conductive ink or paste containing metal particles.

At this time, the electronic device includes multiple integrated circuit chips,
wherein the multiple integrated circuit chips can be horizontally arranged on a single substrate.

Preferably, a vapor chamber is additionally provided on top of the insulating portion.

At this time, the electronic device includes a first package and a second package,
wherein the first package is a lower package containing a chip,
wherein the second package can be stacked on the first package as an upper package containing a chip.

At this time, the insulating portion can be formed on the external surfaces of the first package and second package.

Preferably, the top of the second package is exposed,
and a heat transfer layer is formed on the exposed top.

At this time, a heat dissipation portion can be provided on top of the heat transfer layer.

At this time, a dam means can be formed on a substrate having electronic devices mounted and having a ground pad,
the insulating portion is formed to cover the dam means and electronic devices,
and the electromagnetic shielding layer can be formed on the insulating portion.

Preferably, the dam means is a solid conductive material,
and the shielding layer is electrically connected by contacting the dam means.

At this time, the dam means is a conductive paste or conductive ink,
and the shielding layer can be electrically connected by contacting the dam means.

Preferably, the step of forming the dam means uses a dispensing method or screen printing method.

At this time, the dam means is an insulating material,
and the shielding layer can be directly connected to the ground pad while covering the external surface of the dam means.

Preferably, the height of the dam means is within a range of 80% to 200% of the thickness of the insulating portion.

At this time, the step of forming the insulating portion uses spray coating or jetting method,
and UV curing or thermal curing can be performed after forming the insulating portion.

Preferably, the step of forming the electromagnetic shielding layer uses spray coating or dispensing method.

At this time, it can include regions where the insulating portion or the electromagnetic shielding layer is selectively not formed.

### Advantage Effects

According to the present invention, the semiconductor package enables effective EMI shielding for all electronic devices on the substrate, enables implementation of a thinner and lighter package compared to the conventional shield can structure, reduces process difficulty through a simple coating method, and improves heat dissipation performance through optimized connection with the process chamber. As a result, the long-term reliability of the package is improved due to the enhanced insulation and shielding structure.

Additionally, the semiconductor package of the present invention has the effect that the insulating portion becomes reworkable as flexibility increases under specific conditions.

### BRIEF DESCRIPTION OF DRAWINGS

FIG. 1 is a cross-sectional view according to a first embodiment of the semiconductor package of the present invention.

FIG. 2 is a cross-sectional view according to a second embodiment of the semiconductor package of the present invention.

FIG. 3 is a cross-sectional view according to a third embodiment of the semiconductor package of the present invention.

FIG. 4 is a cross-sectional view according to a fourth embodiment of the semiconductor package of the present invention.

FIG. 5 is a cross-sectional view according to a fifth embodiment of the semiconductor package of the present invention.

FIG. 6 is a cross-sectional view according to a sixth embodiment of the semiconductor package of the present invention.

FIG. 7 is a cross-sectional view according to a seventh embodiment of the semiconductor package of the present invention.

FIG. 8a is a cross-sectional view illustrating a first embodiment of a manufacturing method of the semiconductor package according to the present invention.

FIG. 8b is a perspective view illustrating a dam means of the semiconductor package according to the present invention.

FIG. 9 is a cross-sectional view illustrating a first embodiment of a manufacturing method of the semiconductor package according to the present invention.

FIG. 10 is a cross-sectional view illustrating a first embodiment of a manufacturing method of the semiconductor package according to the present invention.

### DETAILED DESCRIPTION OF THE EMBODIMENTS

Before explaining the present invention in detail, it should be understood that the terms used in this specification are for describing particular embodiments and are not intended to limit the scope of the present invention, which is limited only by the claims attached. All technical and scientific terms used in this specification, unless otherwise stated, have the same meaning as commonly understood by those of ordinary skill in the art.

Throughout this specification and claims, unless otherwise stated, the term “comprise” (comprise, comprises, comprising) means including the mentioned things, steps, or groups of things and steps, and is not used to exclude any other things, steps, or groups of things or groups of steps.

Also, in the drawings, the width, length, thickness, angle, etc. of components may be exaggerated for convenience. The drawings have been described from the observer's viewpoint, and when one component is “on/under” or “above/below” another component, this includes not only cases where it is “directly on/directly under” the other component but also cases where there are other components in between.

In this specification, conformal coating refers to a coating method that is applied to adhere to complex shapes of electronic devices by being applied to a surface with a thickness thin enough to reflect the contours of the surface being coated, and is used in a meaning not limited to specific coating materials.

Meanwhile, various embodiments of the present invention can be combined with any other embodiments unless clearly indicated otherwise. In particular, any feature indicated as preferred or advantageous can be combined with any other feature or features indicated as preferred or advantageous.

The following describes the present invention in more detail with reference to the drawings.

### First Aspect: Semiconductor Package

### First Embodiment

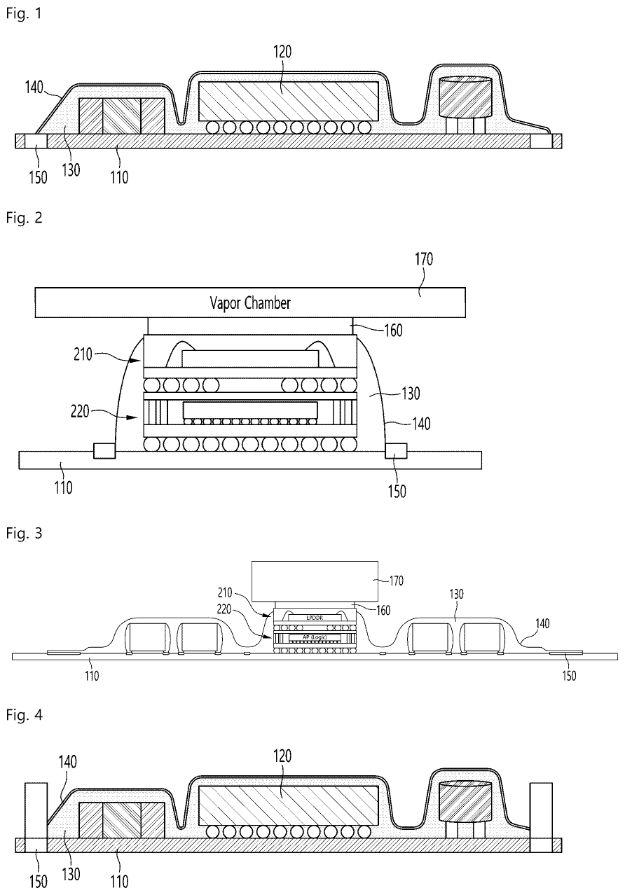

The semiconductor package of the first embodiment proposed in the present invention is a board-level semiconductor package including a substrate (110), an electronic device (120), an insulating portion (130), and an electromagnetic shielding layer (140). FIG. 1 illustrates the board-level semiconductor package according to the present invention.

The substrate (110) is a component that serves as the foundation of the entire system. The substrate (110) mounts various electronic devices (120) and provides electrical connections between them, and is responsible for the structural stability of the entire package.

The substrate (110) typically has a multi-layer PCB structure to support complex circuit configurations. Each layer consists of signal layers, power layers, and ground layers, and signal integrity and power stability are secured through their optimal arrangement. For high-density circuit implementation, fine wiring with line width and line spacing of 10 μm/10 μm or less is applied, and high-density via structures are utilized to support complex connections between various electronic devices.

The conductor layer preferably uses high-purity copper, and surface treatment (e.g., ENEPIG) is applied as needed to improve soldering performance and reliability.

For high-speed signal transmission, it is preferable to design with differential impedance of 85˜100Ω and single-ended impedance of 30˜70Ω, and to apply impedance matching structures when passing between layers to ensure impedance continuity.

For thermal management, it is preferable to secure efficient heat dissipation paths by placing thermal via arrays under devices with high heat generation, and to enhance heat dissipation capability by inserting internal metal heat sinks as needed.

For mechanical stability, layer-to-layer CTE (Coefficient of Thermal Expansion) matching and stress relief structures can be applied to minimize warpage due to thermal stress.

The overall thickness is generally between 0.4 mm and 1.0 mm, and can be adjusted according to the application.

Regarding surface treatment, ENEPIG (Electroless Nickel Electroless Palladium Immersion Gold) treatment in component mounting areas supports various bonding methods (soldering, wire bonding, flip chip bonding), and OSP (Organic Solderability Preservative) treatment is applied to exposed copper areas to prevent oxidation.

The electrical characteristics of the substrate vary depending on the materials used, but generally, the dielectric constant is between 3.0 and 4.5, and the loss tangent has values between 0.002 and 0.020. The Coefficient of Thermal Expansion (CTE) is typically within the range of 10 to 20 ppm/° C., minimizing thermal expansion differences with mounted electronic components.

The main insulating materials of the substrate non-limitatively use improved FR-4 with low dielectric constant and low loss characteristics, or PTFE (Polytetrafluoroethylene) based materials with excellent high-frequency characteristics.

For high-performance semiconductor packages, this substrate can implement wiring with line width and line spacing of 15 μm/15 μm or less by applying fine pitch wiring technology. Additionally, impedance matching design is applied for stable transmission of high-frequency signals.

The substrate of the present invention includes various special functions. It improves electrical performance and space utilization by implementing passive devices such as embedded capacitors and resistors within the substrate.

The electronic device (120) primarily refers to integrated circuit (IC) chips, namely semiconductor chips and passive devices. The electronic device (120) is a critical component that performs the core functions of the semiconductor package. Various types of electronic devices (120) are integrated within a single package, and while performing different functions, they are organically connected to optimize the performance of the entire system.

While electronic devices are not limited, integrated circuit (IC) chips are the most important elements. These are mainly silicon-based semiconductor chips responsible for the system's main functions. Notable examples include application processors (AP), baseband chips, graphics processing units (GPU), and various sensor ICs. These IC chips are manufactured using the latest process technologies (e.g., 7 nm, 5 nm) and satisfy both high performance and low power characteristics.

Memory chips are also important components of SiP. Various types of memory such as DRAM, NAND Flash, and NOR Flash are selectively mounted according to system requirements. Particularly in mobile devices, high-speed, low-power memory such as LPDDR5 or UFS is primarily used.

RF (Radio Frequency) related chips are also frequently included in SiP. These are chips responsible for wireless communication functions, performing functions such as WiFi, Bluetooth, GPS, and 5G modem. These RF chips apply special packaging technology considering high-frequency characteristics, and EMI shielding is very important.

Power Management IC (PMIC) is responsible for stable power supply to the system. It manages multiple voltage levels efficiently and optimizes power consumption. The role of PMIC is very important as various chips within the SiP require different voltages.

In addition, various sensor chips (accelerometer sensors, gyro sensors, fingerprint sensors, etc.), audio codecs, display driver ICs, and others can be included. By integrating these chips with various functions into a single package, both system miniaturization and performance optimization can be achieved simultaneously.

Passive devices are also important components. Mainly capacitors, resistors, and inductors are used, and these are primarily provided in ultra-small chip component form. These passive devices perform important roles such as power stabilization, noise removal, and impedance matching.

In this invention's board-level package, optimal placement and connection structures are provided considering the characteristics of these various electronic devices. Particularly, for RF chips handling high-frequency signals, individual shielding structures are applied to minimize interference, and for APs or GPUs with high heat generation, heat dissipation paths are optimized to ensure stable operation.

The connection method of electronic devices is also an important consideration. Various connection technologies such as wire bonding, flip chip bonding, and TSV (Through Silicon Via) are used. High-performance ICs mainly use flip chip bonding method to optimize electrical performance, while memory chips and other auxiliary chips use wire bonding method to increase cost efficiency.

The insulating portion (130) is an insulating part formed on the external surfaces of the substrate (110) and electronic devices (120), which is a conformal coating layer in this invention. One of the key features of the insulating portion (130) used in this invention is that it is a conformal layer. The conformal insulating portion (130) refers to a layer that is uniformly coated following the surface topology of electronic components and substrate (110).

The conformal insulating portion (130) can form an insulating part of uniform thickness even on complex 3D structure surfaces, and since it is coated following the fine structures and shapes of electronic components, it can maintain the gaps between components and fine structures, making it very advantageous for high-density packaging.

Also, since liquid molding material is evenly applied to all surfaces, it can minimize the occurrence of voids or bubbles that can occur in conventional molding methods.

Additionally, conformal coating enables selective coating of specific areas. This allows flexible design such as exposing certain areas for heat management or RF performance optimization.

For conformal coating, the viscosity of the coating material is preferably 50-500 cPs (based on 25° C.). Exceeding this range makes spraying difficult, and if too low, excessive flowability makes uniform coating difficult.

During coating, the spray nozzle pressure is preferably 10-60 psi (69-414 kPa). Below this range results in insufficient coverage, and exceeding this range risks overspray or droplet formation.

UV-curable polymer materials are used, which have excellent insulation characteristics, heat resistance, and low moisture absorption. Spray or jetting methods are used as coating methods. These methods can form coating layers of uniform thickness even on complex-shaped electronic devices, providing superior coverage compared to conventional transfer molding methods.

The thickness of the insulating portion is controlled within the range of 10 to 200 μm. First, if the insulating portion thickness exceeds 200 μm, it increases thermal resistance, hindering heat dissipation from internal heat-generating devices, and degrades package reliability by increasing internal stress due to differences in thermal expansion coefficients. Conversely, if the insulating portion thickness is less than 50 μm, it fails to secure sufficient insulation distance, degrading electrical insulation performance, and cannot effectively buffer repetitive expansion and contraction stress from thermal cycles.

After coating, it undergoes a UV curing process, during which UV energy of 3000 to 10000 mJ is irradiated for curing. The UV curing method provides advantages of faster curing speed and lower thermal stress compared to thermal curing methods.

The insulating portion of the present invention has re-work capability. Re-work refers to the process of performing modification, rework, or repair on manufactured products or components, which plays an important role in improving production efficiency and product quality.

As long as the material satisfies the aforementioned conditions, the material for the insulating portion is not limited, and the insulating portion material uses either thermal curing materials (for example, thermosetting epoxy) or UV curing materials (for example, UV-curable acrylate). Thermosetting epoxy provides high heat resistance and strength with excellent electrical stability characteristics, while UV acrylate provides fast curing speed and excellent re-workability advantages. The Breakdown Voltage of the insulating portion meets the insulation requirements of PCB (Printed Circuit Board) and is designed to withstand voltage stress.

For thermal curing materials, while re-workability is limited to about 50%, it provides high mechanical strength and durability, whereas the UV curing material's insulating portion allows 100% re-workability.

The insulating portion (130) may not be coated on top of the integrated circuit (IC) chip. Instead, a heat transfer layer (160) is formed on the top using a silicon pad as TIM (Thermal Interface Material) and connected to the heat dissipation portion (170). This structure greatly improves the package's thermal management capability. The heat dissipation portion (170) can be, for example, a vapor chamber.

By effectively transferring heat generated from high-performance chips to the vapor chamber and releasing it, the system's stability and performance are improved.

The UV-curable molding material of the insulating portion (130) preferably has a low dielectric constant (typically 3.0 to 4.0) and low dielectric loss factor (typically 0.01 to 0.03). This plays an important role in maintaining high-frequency signal integrity. These characteristics are particularly important in high-frequency applications such as 5G.

After curing, the insulating portion (130) has high hardness (Shore D hardness 70˜90) and excellent impact resistance. This plays an important role in protecting internal electronic devices from external impacts. Additionally, the coefficient of thermal expansion (CTE) is adjusted to be similar to that of the substrate and chip to minimize deformation due to thermal stress.

Furthermore, the UV-curable molding material of the insulating portion (130) has excellent moisture resistance and heat resistance. It guarantees moisture resistance reliability for over 1000 hours under 85° C./85% RH conditions and maintains stable performance in a temperature range from −40° C. to 125° C.

Plasma treatment can be applied to the insulating portion surface. This increases surface energy, improving the wettability and adhesion of conductive paste coated on the insulating portion.

Also, to increase adhesion between the insulating portion and electromagnetic shielding layer, applying silane coupling agents (e.g., 3-glycidoxypropyl trimethoxysilane, GPTMS, 3-methacryloxypropyl trimethoxysilane (MPTMS)) with functional groups such as epoxy or acrylate functional groups to the insulating portion surface can enhance adhesion through chemical bonding with the conductive paste.

The electromagnetic shielding layer (140) plays an important role in protecting internal electronic components from electromagnetic interference (EMI), is formed on the insulating portion (130), and is applied using conformal coating technology.

The shielding layer preferably has shielding performance of over 60 dB, maintains surface resistance below 30 mΩ/sq to secure high electrical conductivity, and satisfies ASTM D3359 standard 5B or higher for adhesion between the shielding layer and insulation layer to prevent coating delamination.

The shielding layer (140) material primarily uses conductive ink or paste containing metal particles (e.g., silver, copper, nickel). This material has excellent electrical conductivity and can effectively block electromagnetic waves and magnetic fields. After coating, it undergoes thermal curing at 120° C. for 1 hour. This thermal curing process serves to increase the mechanical strength of the shielding layer and stabilize its electrical characteristics.

The shielding layer (140) of the present invention provides bi-directional shielding functionality that not only blocks external electromagnetic waves but also prevents electromagnetic waves generated inside the package from being emitted externally. This greatly improves the performance and reliability of SiP packages in high-frequency operating environments.

Another important characteristic of the shielding layer (140) is that it can be electrically connected to the ground pad (150) of the substrate (110). For this purpose, selective coating is performed when forming the shielding layer (140) to connect with the ground pad (150) of the substrate (110), allowing the shielding layer (140) material to directly contact this ground pad (150). This ground connection maximizes the shielding effect and also improves electrostatic discharge (ESD) protection functionality.

For forming the electromagnetic shielding layer (140), spray coating or jetting methods can be used. Both methods have the advantage of being able to form uniform and continuous shielding layers on complex 3D structured SiP package surfaces. Particularly, the spray coating method enables quick and uniform coating over large areas, while the jetting method is useful when precise pattern formation is needed.

To achieve conformal coating characteristics when forming the electromagnetic shielding layer, the spray nozzle pressure is maintained at 10˜60 psi to ensure uniform spraying of fine particles, the distance between nozzle and substrate is set at 11˜50 mm to form appropriate spray patterns, and the spray angle is maintained at 70˜110 degrees relative to the substrate to obtain uniform coating thickness.

The spray gun movement speed is controlled at 10˜500 mm/s to achieve desired thickness, and the coating material viscosity is preferably maintained at 200˜400 cPs to secure appropriate flow and coverage. Perfect shielding layers without pinholes or discontinuities can be formed using multiple pass coating techniques.

Through such precise process control, this invention's electromagnetic shielding layer can uniformly cover all surfaces of the SiP package while selectively connecting to desired parts (e.g., ground pads).

Also, to prevent cracking or delamination that might occur during thermal curing, it is preferable to slowly control the temperature rise rate to 2˜3° C./min up to the curing temperature, with the cooling process proceeding at a similar rate.

When forming the electromagnetic shielding layer on the insulating portion, the CTE difference between the insulating portion and electromagnetic shielding layer is less than 20 ppm/° C., more preferably less than 10 ppm/° C. For this purpose, the conductive paste can contain inorganic fillers (for example, silica or alumina) at 5 to 250 weight % of the total paste weight.

Additionally, it is preferable for the electromagnetic shielding layer and insulating portion to have the same curing conditions. For example, using UV-curable conductive paste with UV-curable insulating portions is advantageous for process efficiency.

Also, it is preferable for the binder resin of the conductive paste in the electromagnetic shielding layer to form chemical bonds with the insulating portion material. For example, conductive paste using epoxy binder is suitable for epoxy-based insulating portions.

### Second Embodiment

The semiconductor package of the second embodiment proposed in this invention applies to POP (Package on Package) structured semiconductor chips. The POP structure stacks and connects two or more chip packages vertically, where electromagnetic (EMI) shielding is a very critical issue. Without electromagnetic shielding, closely placed chips can cause signal interference, leading to performance degradation and signal errors.

Conventional electromagnetic shielding prevents electromagnetic waves from being emitted externally and blocks incoming electromagnetic waves by placing metal shield caps over chips.

Metal caps are mainly made of highly conductive metals such as copper or aluminum and physically cover chips to block electromagnetic interference. However, since shield caps physically cover chips, they limit flexibility in PCB (Printed Circuit Board) design and component placement. Particularly, if the shield cap is not properly grounded, it can worsen electromagnetic interference, requiring design solutions for grounding issues, which complicates system design.

Another conventional electromagnetic shielding method is metal coating on chips using vacuum deposition or plasma. Vacuum deposition and sputtering processes require high vacuum equipment and maintenance costs due to their high vacuum requirements, while plasma deposition processes have environmental issues with process contaminants and waste generation.

Therefore, this embodiment's semiconductor package includes a substrate (110), first package (210), second package (220), insulating portion (130), electromagnetic shielding layer (140), heat transfer layer (160), and heat dissipation portion (170). FIG. 2 shows a cross-sectional view according to the second embodiment of the semiconductor package of this invention.

The substrate (110) is where each package is installed and serves as the base for forming the insulating portion (130) and shielding layer (140), with ground pads (150) provided on its surface for grounding. The electrical characteristics of the substrate vary depending on materials used, but generally have a dielectric constant between 3.0 and 4.5, and loss tangent values between 0.002 and 0.020. The Coefficient of Thermal Expansion (CTE) typically ranges from 10 to 20 ppm/° C., minimizing thermal expansion differences with mounted electronic components.

The first package (210) is the package of the first chip, and the second package (220) is the package of the second chip. While the components of each package are not limited, as shown, they typically include substrate, chip, molding portion, and solder balls. FIG. 2 shows POP according to one embodiment of this invention.

The first package (210) is the package of the first chip, and the second package (220) is the package of the second chip. While the components of each chip are not limited, they typically include substrate, chip, molding portion, and solder balls. This allows flexible design such as exposing certain areas for thermal management or RF performance optimization.

The insulating portion (130) uses UV-curable polymer material, which has excellent insulation characteristics, heat resistance, and low moisture absorption. For coating methods, spray or jetting methods are used. These methods can form coating layers of uniform thickness even on electronic devices with complex shapes.

The thickness of the insulating portion (130) is controlled within a range of 10 to 200 μm. First, if the insulating portion thickness exceeds 200 μm, it increases thermal resistance, hindering heat dissipation from internal heat-generating devices, and reduces package reliability by increasing internal stress due to thermal expansion coefficient differences. Conversely, if the insulating portion (130) thickness is less than 50 μm, it fails to secure sufficient insulation distance, degrading electrical insulation performance, and cannot effectively buffer repetitive expansion and contraction stress from thermal cycles.

After coating, it undergoes a UV curing process, during which UV energy of 3000 to 10000 mJ is irradiated for curing. The UV curing method provides advantages of faster curing speed and lower thermal stress compared to thermal curing methods.

The insulating portion (130) of this invention has re-work capability. Re-work refers to the process of performing modification, rework, or repair on manufactured products or components, which plays an important role in improving production efficiency and product quality.

As long as the material satisfies the aforementioned conditions, the material for the insulating portion is not limited, for example, UV-curable acrylate resin, silicone-modified acrylate resin, photodegradable epoxy acrylate resin can be used.

The insulating portion (130) materials can undergo thermally activated decomposition under specific conditions, for example, at heat treatment above 100° C., where heat partially releases the material's cross-linking bonds, reducing material rigidity and increasing flexibility.

Additionally, heat treatment can change the microstructure of the coating layer, increasing permeability to certain solvents. Also, heat treatment can weaken interfacial adhesion between the coating layer and substrate, and when specific chemicals (e.g., weak acidic solution) are applied simultaneously with heat treatment, chemical decomposition of the coating material can be accelerated.

Some coating materials can undergo phase transition from solid to high-viscosity liquid state at specific temperatures. While this is not complete melting, it represents a change in the material's physical state.

The insulating portion (130) may not be coated on top of the integrated circuit (IC) chip, and instead, a heat transfer portion (160) is provided at the top. The heat transfer portion (160) connects to the heat dissipation portion (170) using a silicon pad as TIM (Thermal Interface Material). This structure greatly improves the package's thermal management capability. By effectively transferring and releasing heat generated from high-performance chips to the heat dissipation portion (170), it improves system stability and performance.

The UV-curable molding material of the insulating portion (130) preferably has a low dielectric constant (typically 3.0 to 4.0) and low dielectric loss factor (typically 0.01˜0.03). This plays an important role in maintaining high-frequency signal integrity. These characteristics are particularly important in high-frequency applications such as 5G.

After curing, the insulating portion (130) has high hardness (Shore D hardness 70˜90) and excellent impact resistance. This plays an important role in protecting internal electronic devices from external impacts. Additionally, the coefficient of thermal expansion (CTE) is adjusted to be similar to that of the substrate and chip to minimize deformation due to thermal stress.

Furthermore, the UV-curable molding material of the insulating portion (130) has excellent moisture resistance and heat resistance. It guarantees moisture resistance reliability for over 1000 hours under 85° C./85% RH conditions and maintains stable performance in a temperature range from −40° C. to 125° C.

Meanwhile, in this embodiment, the insulating portion can be either conformal or non-conformal.

The non-conformal case is when it is not uniformly coated following the external shape of the first package (210) and second package (220).

The conformal case refers to when it is uniformly coated following the external shape of the first package and second package. Conformal insulating portions can form insulating portions of uniform thickness even on complex 3D structured surfaces, and since it is coated following the fine structures and shapes of electronic components, it can maintain gaps between components and fine structures, making it very advantageous for high-density packaging. Additionally, since liquid molding material is evenly applied to all surfaces, it can minimize the occurrence of voids or bubbles that might occur in conventional molding methods.

For conformal coating, the coating material's viscosity is preferably 50-500 cPs (based on 25° C.). Exceeding this range makes spraying difficult, and if too low, excessive flow makes uniform coating difficult.

During coating, the spray nozzle pressure is preferably 10-60 psi (69-414 kPa). Below this range results in insufficient coverage, and exceeding this range risks overspray or droplet formation.

The electromagnetic shielding layer (140) plays an important role in protecting internal electronic components from electromagnetic interference (EMI), is formed on the insulating portion, and is applied using conformal coating technology.

The shielding layer preferably has shielding performance of over 60 dB, maintains surface resistance below 30 mΩ/sq to secure high electrical conductivity, and satisfies ASTM D3359 standard 5B or higher for adhesion between the shielding layer and insulation layer to prevent coating delamination.

The thickness of the shielding layer (140) is controlled within 5˜30 μm, more preferably 5 to 20 μm range, which provides effective EMI shielding performance while minimizing the overall package thickness.

The shielding layer (140) material primarily uses conductive ink or paste containing metal particles (e.g., silver, copper, nickel). This material has excellent electrical conductivity and can effectively block electromagnetic waves and magnetic fields. After coating, it undergoes thermal curing at 120° C. for 1 hour. This thermal curing process serves to increase the mechanical strength of the shielding layer and stabilize its electrical characteristics.

The shielding layer (140) of this invention provides bi-directional shielding functionality that not only blocks external electromagnetic waves but also prevents electromagnetic waves generated inside the package from being emitted externally. This greatly improves the performance and reliability of SiP packages in high-frequency operating environments.

Another important characteristic of the shielding layer is that it can be electrically connected to the substrate's ground pad (150). For this purpose, selective coating is performed when forming the shielding layer to connect with the ground pad (150) of the substrate, allowing the shielding layer material to directly contact this ground pad. This ground connection maximizes the shielding effect and also improves electrostatic discharge (ESD) protection functionality.

For forming the electromagnetic shielding layer, spray coating or jetting methods can be used. Both methods have the advantage of being able to form uniform and continuous shielding layers on complex 3D structured SiP package surfaces. Particularly, the spray coating method enables quick and uniform coating over large areas, while the jetting method is useful when precise pattern formation is needed.

To achieve conformal coating characteristics when forming the electromagnetic shielding layer (140), the spray nozzle pressure is maintained at 10˜60 psi to ensure uniform spraying of fine particles, the distance between nozzle and substrate is set at 11˜50 mm to form appropriate spray patterns, and the spray angle is maintained at 70˜110 degrees relative to the substrate to obtain uniform coating thickness.

The spray gun movement speed is controlled at 10˜500 mm/s to achieve desired thickness, and the coating material viscosity is preferably maintained at 200˜400 cPs to secure appropriate flow and coverage. Perfect shielding layers without pinholes or discontinuities can be formed using multiple pass coating techniques.

Through such precise process control, this invention's electromagnetic shielding layer (140) can uniformly cover all surfaces of the SiP package while selectively connecting to desired parts (e.g., ground pads).

Also, to prevent cracking or delamination that might occur during thermal curing, it is preferable to slowly control the temperature rise rate to 2˜3° C./min up to the curing temperature, with the cooling process proceeding at a similar rate.

### Third Embodiment

The third embodiment of this invention includes a substrate (110), electronic devices including first package (210) and second package (220), insulating portion (130), electromagnetic shielding layer (140), heat transfer layer (160), and heat dissipation portion (170). FIG. 3 shows a cross-sectional view according to the third embodiment of the semiconductor package of this invention. Accordingly, the board level semiconductor package according to this embodiment differs from the second embodiment in that it is board level, and differs from the first embodiment in that it includes POP structured semiconductor electronic devices.

In this embodiment, both the insulating portion (130) and electromagnetic shielding layer (140) are formed by conformal coating, where the insulating portion (130) is 10˜200 μm, and the insulating portion (130) becomes flexible under specific conditions to be reworkable. At this time, spray or jetting methods are used for coating.

Additionally, the insulating portion (130) does not cover the ground pad (150), and the electromagnetic shielding layer (140) is electrically connected to the ground pad (150).

Since the descriptions of the insulating portion, electromagnetic shielding layer, heat transfer layer, and heat dissipation portion are identical to the previously described embodiments, detailed explanations are omitted.

### Fourth Embodiment

The semiconductor package of the first embodiment proposed in this invention is a board-level semiconductor package including a substrate (110), electronic device (120), insulating portion (130), electromagnetic shielding layer (140), and dam means. FIG. 4 shows a cross-sectional view according to the fourth embodiment of the board-level semiconductor package of this invention.

The substrate (110) is a component that serves as the foundation of the entire system. The substrate (110) mounts various electronic devices (120) and provides electrical connections between them, and is responsible for the structural stability of the entire package.

The substrate (110) typically has a multi-layer PCB structure to support complex circuit configurations. Each layer consists of signal layers, power layers, and ground layers, and signal integrity and power stability are secured through their optimal arrangement. For high-density circuit implementation, fine wiring with line width and line spacing of 10 μm/10 μm or less is applied, and high-density via structures are utilized to support complex connections between various electronic devices.

The conductor layer preferably uses high-purity copper, and surface treatment (e.g., ENEPIG) is applied as needed to improve soldering performance and reliability.

For high-speed signal transmission, it is preferably designed with differential impedance of 85˜100Ω and single-ended impedance of 30˜70Ω, and impedance matching structures are applied when passing between layers to ensure impedance continuity.

For thermal management, it is preferable to secure efficient heat dissipation paths by placing thermal via arrays under devices with high heat generation, and to enhance heat dissipation capability by inserting internal metal heat sinks as needed.

For mechanical stability, layer-to-layer CTE (Coefficient of Thermal Expansion) matching and stress relief structures can be applied to minimize warpage due to thermal stress.

The overall thickness is generally between 0.4 mm and 1.0 mm, and can be adjusted according to the application.

Regarding surface treatment, ENEPIG (Electroless Nickel Electroless Palladium Immersion Gold) treatment in component mounting areas supports various bonding methods (soldering, wire bonding, flip chip bonding), and OSP (Organic Solderability Preservative) treatment is applied to exposed copper areas to prevent oxidation.

The electrical characteristics of the substrate vary depending on the materials used, but generally, the dielectric constant is between 3.0 and 4.5, and the loss tangent has values between 0.002 and 0.020. The Coefficient of Thermal Expansion (CTE) is typically within the range of 10 to 20 ppm/° C., minimizing thermal expansion differences with mounted electronic components.

The main insulating materials of the substrate use improved FR-4 with low dielectric constant and low loss characteristics, or PTFE (Polytetrafluoroethylene) based materials with excellent high-frequency characteristics.

For high-performance semiconductor packages, this substrate can implement wiring with line width and line spacing of 15 μm/15 μm or less by applying fine pitch wiring technology. Additionally, impedance matching design is applied for stable transmission of high-frequency signals.

The substrate of this invention includes various special functions. It improves electrical performance and space utilization by implementing passive devices such as embedded capacitors and resistors within the substrate.

The electronic device (120) primarily refers to integrated circuit (IC) chips, namely semiconductor chips and passive devices. The electronic device (120) is an important component that performs the core functions of the semiconductor package. Various types of electronic devices (120) are integrated within a single package, and while performing different functions, they are organically connected to optimize the performance of the entire system.

While the electronic devices are not limited, the integrated circuit (IC) chip is the most important element. This is mainly a silicon-based semiconductor chip responsible for the system's main functions. Representative examples include application processors (AP), baseband chips, graphics processing units (GPU), and various sensor ICs. These IC chips are manufactured using the latest process technology (e.g., 7 nm, 5 nm) and simultaneously satisfy high performance and low power characteristics.

Memory chips are also important components of SiP. Various types of memory such as DRAM, NAND Flash, NOR Flash are selectively mounted according to system requirements. Particularly in mobile devices, high-speed, low-power memory such as LPDDR5 or UFS is mainly used.

RF (Radio Frequency) related chips are also frequently included in SiP. These are chips responsible for wireless communication functions, performing functions such as WiFi, Bluetooth, GPS, and 5G modem. These RF chips apply special packaging technology considering high-frequency characteristics, and EMI shielding is very important.

Power Management IC (PMIC) is responsible for stable power supply to the system. It efficiently manages multiple voltage levels and optimizes power consumption. The role of PMIC is very important as various chips within SiP require different voltages.

Additionally, various sensor chips (accelerometer, gyro sensor, fingerprint sensor, etc.), audio codecs, display driver ICs can be included. By integrating chips with these various functions into a single package, both system miniaturization and performance optimization can be achieved simultaneously.

Passive devices are also important components. Mainly capacitors, resistors, inductors are used, primarily provided in ultra-small chip component form. These passive devices perform important roles such as power stabilization, noise removal, and impedance matching.

In this invention's board-level package, optimal placement and connection structures are provided considering the characteristics of these various electronic devices. Particularly, for RF chips handling high-frequency signals, individual shielding structures are applied to minimize interference, and for AP or GPU with high heat generation, heat dissipation paths are optimized to ensure stable operation.

The connection method of electronic devices is also an important consideration. Various connection technologies such as wire bonding, flip chip bonding, TSV (Through Silicon Via) are used. High-performance ICs mainly use flip chip bonding method to optimize electrical performance, while memory chips and other auxiliary chips use wire bonding method to increase cost efficiency.

The insulating portion (130) is an insulating layer formed on the external surfaces of the substrate (110) and electronic devices (120), which in this invention is a conformal coating layer. One of the core features of the insulating portion (130) used in this invention is that it is a conformal layer. The conformal insulating portion (130) refers to a layer that is uniformly coated following the surface contours of electronic components and substrate (110).

The conformal insulating portion (130) can form an insulating portion of uniform thickness even on complex 3D structured surfaces, and since it is coated following the fine structures and shapes of electronic components, it can maintain gaps between components and fine structures, making it very advantageous for high-density packaging.

Additionally, since liquid molding material is evenly applied to all surfaces, it can minimize the occurrence of voids or bubbles that might occur in conventional molding methods.

Furthermore, conformal coating allows selective coating of specific areas. This enables flexible design such as exposing certain areas for thermal management or RF performance optimization.

For conformal coating, the coating material's viscosity is preferably 50-500 cPs (based on 25° C.). Exceeding this range makes spraying difficult, and if too low, excessive flow makes uniform coating difficult.

During coating, the spray nozzle pressure is preferably 10-60 psi (69-414 kPa). Below this range results in insufficient coverage, and exceeding this range risks overspray or droplet formation.

UV-curable polymer material is used, which has excellent insulation characteristics, heat resistance, and low moisture absorption. For coating methods, spray or jetting methods are used. These methods can form coating layers of uniform thickness even on electronic devices with complex shapes, providing superior coverage compared to conventional transfer molding methods.

The thickness of the insulating portion is controlled within a range of 10 to 200 μm.

First, if the insulating portion thickness exceeds 200 μm, it increases thermal resistance, hindering heat dissipation from internal heat-generating devices, and reduces package reliability by increasing internal stress due to thermal expansion coefficient differences. Conversely, if the insulating portion thickness is less than 50 μm, it fails to secure sufficient insulation distance, degrading electrical insulation performance, and cannot effectively buffer repetitive expansion and contraction stress from thermal cycles.

After coating, it undergoes a UV curing process, during which UV energy of 3000 to 10000 mJ is irradiated for curing. The UV curing method provides advantages of faster curing speed and lower thermal stress compared to thermal curing methods.

The insulating portion of this invention has re-work capability. Re-work refers to the process of performing modification, rework, or repair on manufactured products or components, which plays an important role in improving production efficiency and product quality.

As long as the material satisfies the aforementioned conditions, the material for the insulating portion is not limited, and the insulating portion material uses either thermal curing materials (for example, thermosetting epoxy) or UV curing materials (for example, UV-curable acrylate). Thermosetting epoxy provides high heat resistance and strength with excellent electrical stability characteristics, while UV acrylate provides fast curing speed and excellent re-workability advantages. The Breakdown Voltage of the insulating portion meets the insulation requirements of PCB (Printed Circuit Board) and is designed to withstand voltage stress.

For thermal curing materials, while re-workability is limited to about 50%, it provides high mechanical strength and durability, while the UV curing material's insulating portion allows 100% re-workability.

The insulating portion (130) may not be coated on top of the integrated circuit (IC) chip. Instead, a heat transfer layer (160) is formed on the top using a silicon pad as TIM (Thermal Interface Material) and connected to the heat dissipation portion (170). This structure greatly improves the package's thermal management capability. The heat dissipation portion (170) can be, for example, a vapor chamber.

By effectively transferring heat generated from high-performance chips to the vapor chamber and releasing it, the system's stability and performance are improved.

The UV-curable molding material of the insulating portion (130) preferably has a low dielectric constant (typically 3.0 to 4.0) and low dielectric loss factor (typically 0.01-0.03). This plays an important role in maintaining high-frequency signal integrity. These characteristics are particularly important in high-frequency applications such as 5G.

After curing, the insulating portion (130) has high hardness (Shore D hardness 70˜90) and excellent impact resistance. This plays an important role in protecting internal electronic devices from external impacts. Additionally, the coefficient of thermal expansion (CTE) is adjusted to be similar to that of the substrate and chip to minimize deformation due to thermal stress.

Furthermore, the UV-curable molding material of the insulating portion (130) has excellent moisture resistance and heat resistance. It guarantees moisture resistance reliability for over 1000 hours under 85° C./85% RH conditions and maintains stable performance in a temperature range from −40° C. to 125° C.

The electromagnetic shielding layer (140) plays an important role in protecting internal electronic components from electromagnetic interference (EMI), is formed on the insulating portion (130), and is applied using conformal coating technology.

The shielding layer preferably has shielding performance of over 60 dB, maintains surface resistance below 30 mΩ/sq to secure high electrical conductivity, and satisfies ASTM D3359 standard 5B or higher for adhesion between the shielding layer and insulation layer to prevent coating delamination.

The thickness of the shielding layer (140) is controlled within 5˜30 μm, more preferably 5 to 20 μm range, which provides effective EMI shielding performance while minimizing the overall package thickness.

The shielding layer (140) material primarily uses conductive ink or paste containing metal particles (e.g., silver, copper, nickel). This material has excellent electrical conductivity and can effectively block electromagnetic waves and magnetic fields. After coating, it undergoes thermal curing at 120° C. for 1 hour. This thermal curing process serves to increase the mechanical strength of the shielding layer and stabilize its electrical characteristics.

The shielding layer (140) of this invention provides bi-directional shielding functionality that not only blocks external electromagnetic waves but also prevents electromagnetic waves generated inside the package from being emitted externally. This greatly improves the performance and reliability of SiP packages in high-frequency operating environments.

Another important characteristic of the shielding layer (140) is that it can be electrically connected to the ground pad (150) of the substrate (110). For this purpose, selective coating is performed when forming the shielding layer (140) to connect with the ground pad (150) of the substrate (110), allowing the shielding layer (140) material to directly contact this ground pad (150). This ground connection maximizes the shielding effect and also improves electrostatic discharge (ESD) protection functionality.

For forming the electromagnetic shielding layer (140), spray coating or Inkjet methods can be used. Both methods have the advantage of being able to form uniform and continuous shielding layers on complex 3D structured SiP package surfaces. Particularly, the spray coating method enables quick and uniform coating over large areas, while the dispensing method is useful when precise pattern formation is needed.

To achieve conformal coating characteristics when forming the electromagnetic shielding layer, the spray nozzle pressure is maintained at 10˜60 psi to ensure uniform spraying of fine particles, the distance between nozzle and substrate is set at 1˜150 mm to form appropriate spray patterns, and the spray angle is maintained at 70˜110 degrees relative to the substrate to obtain uniform coating thickness.

The spray gun movement speed is controlled at 10˜500 mm/s to achieve desired thickness, and the coating material viscosity is preferably maintained at 200˜400 cPs to secure appropriate flow and coverage. Perfect shielding layers without pinholes or discontinuities can be formed using multiple pass coating techniques.

Through such precise process control, this invention's electromagnetic shielding layer can uniformly cover all surfaces of the SiP package while selectively connecting to desired parts (e.g., ground pads).

Also, to prevent cracking or delamination that might occur during thermal curing, it is preferable to slowly control the temperature rise rate to 2˜3° C./min up to the curing temperature, with the cooling process proceeding at a similar rate.

The shielding layer is connected to the dam means and electrically connected to the ground electrode. The conductive dam is formed higher than the insulating layer thickness, naturally creating electrical connection after shielding layer coating. This ground connection improves electromagnetic shielding efficiency while also enhancing magnetic field and electrostatic discharge (ESD) protection functionality.

The dam means (180) is a means provided to prevent overflow of the insulating portion onto the ground electrode during the insulating portion coating process. If the insulating portion flows to the ground electrode, the ground electrode becomes insulated, significantly reducing the shielding function of the electromagnetic shielding layer, thus preventing this.

In this embodiment, the dam means is provided in the form of forming a metal dam of certain height with electrical conductivity. The dam means is provided on the position where the ground pad is formed on the substrate with electronic devices, enabling electrical connection with the ground pad, simultaneously blocking the flow of the insulating portion and achieving electrical connection with the electromagnetic shielding layer.

The dam means is preferably formed with a width of 300˜500 μm and a height of 300˜700 μm.

### Fifth Embodiment

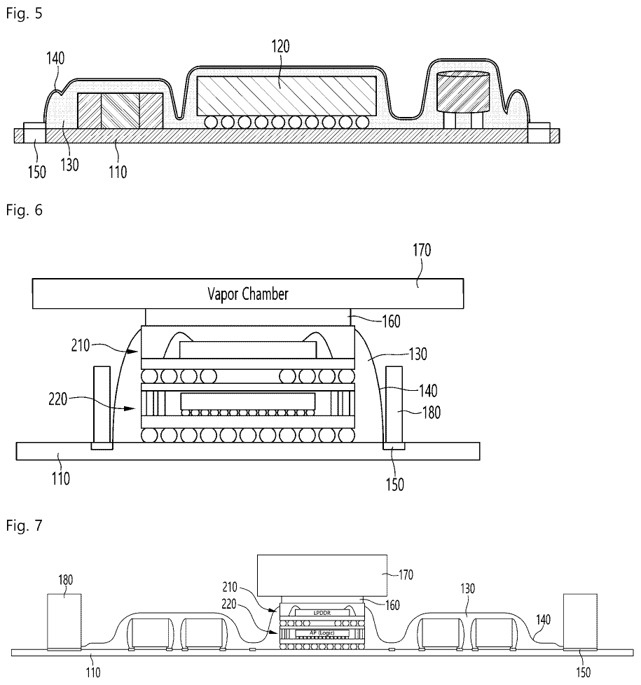

The fifth embodiment differs in that the dam means (180) is provided in the form of forming an insulating dam. In this case, the dam means (180) has the function of preventing the flow of the insulating portion during insulating portion formation and does not make electrical connection with the ground pad. FIG. 5 shows a cross-sectional view according to the fifth embodiment of the semiconductor package of this invention.

Therefore, the dam means (180) of this embodiment is not formed on the ground pad (150), but is provided on the inner side of the ground pad to prevent the coating liquid forming the insulating portion from approaching the ground pad.

The electromagnetic shielding layer is coated on all substrate top surfaces and electronic device top surfaces including the top surface of the dam means (180), and is also formed on the top surface of the ground pad (150) to make electrical connection with the ground pad.

### Sixth Embodiment

The semiconductor package of the sixth embodiment proposed in this invention applies to POP (Package on Package) structured semiconductor chips. The POP structure stacks and connects two or more chip packages vertically, where electromagnetic (EMI) shielding is a very critical issue. Without electromagnetic shielding, closely placed chips can cause signal interference, leading to performance degradation and signal errors.

Conventional electromagnetic shielding prevents electromagnetic waves from being emitted externally and blocks incoming electromagnetic waves by placing metal shield caps over chips.

Metal caps are mainly made of highly conductive metals such as copper or aluminum and physically cover chips to block electromagnetic interference. However, since shield caps physically cover chips, they limit flexibility in PCB (Printed Circuit Board) design and component placement. Particularly, if the shield cap is not properly grounded, it can worsen electromagnetic interference, requiring design solutions for grounding issues, which complicates system design.

Another conventional electromagnetic shielding is metal coating on chips using vacuum deposition or plasma. Vacuum deposition and sputtering processes require high vacuum equipment and maintenance costs due to their high vacuum requirements, while plasma deposition processes have environmental issues with process contaminants and waste generation.

Therefore, this embodiment's semiconductor package includes a substrate (110), first package (210), second package (220), insulating portion (130), electromagnetic shielding layer (140), heat transfer layer (160), heat dissipation portion (170), and dam means (180). FIG. 6 shows a cross-sectional view according to the sixth embodiment of the semiconductor package of this invention.

The substrate (110) is where each package is installed and serves as the base for forming the insulating portion (130) and shielding layer (140), with ground pads (150) provided on its surface for grounding. The electrical characteristics of the substrate vary depending on the materials used, but generally, the dielectric constant is between 3.0 and 4.5, and the loss tangent has values between 0.002 and 0.020. The Coefficient of Thermal Expansion (CTE) is typically within the range of 10 to 20 ppm/° C., minimizing thermal expansion differences with mounted electronic components.

The first package (210) is the package of the first chip, and the second package (220) is the package of the second chip. While the components of each package are not limited, as shown, they typically include substrate, chip, molding portion, and solder balls. That is, FIG. 6 shows POP according to one embodiment of this invention. This allows flexible design such as exposing certain areas for thermal management or RF performance optimization.

The insulating portion (130) uses UV-curable polymer material, which has excellent insulation characteristics, heat resistance, and low moisture absorption. For coating methods, spray or jetting methods are used. These methods can form coating layers of uniform thickness even on electronic devices with complex shapes.

The thickness of the insulating portion (130) is controlled within a range of 10 to 200 μm. First, if the insulating portion thickness exceeds 200 μm, it increases thermal resistance, hindering heat dissipation from internal heat-generating devices, and reduces package reliability by increasing internal stress due to thermal expansion coefficient differences. Conversely, if the insulating portion (130) thickness is less than 50 μm, it fails to secure sufficient insulation distance, degrading electrical insulation performance, and cannot effectively buffer repetitive expansion and contraction stress from thermal cycles.

After coating, it undergoes a UV curing process, during which UV energy of 3000 to 10000 mJ is irradiated for curing. The UV curing method provides advantages of faster curing speed and lower thermal stress compared to thermal curing methods. Curing is preferably performed below 100° C.

The insulating portion (130) of this invention has re-work capability. Re-work refers to the process of performing modification, rework, or repair on manufactured products or components, which plays an important role in improving production efficiency and product quality.

As long as the material satisfies the aforementioned conditions, the material for the insulating portion is not limited, for example, UV-curable acrylate resin, silicone-modified acrylate resin, photodegradable epoxy acrylate resin can be used.

The insulating portion (130) materials can undergo thermally activated decomposition under specific conditions, for example, at heat treatment above 100° C., where heat partially releases the material's cross-linking bonds, reducing material rigidity and increasing flexibility.

Additionally, heat treatment can change the microstructure of the coating layer, increasing permeability to certain solvents. Also, heat treatment can weaken interfacial adhesion between the coating layer and substrate, and when specific chemicals (e.g., weak acidic solution) are applied simultaneously with heat treatment, chemical decomposition of the coating material can be accelerated.

Some coating materials can undergo phase transition from solid to high-viscosity liquid state at specific temperatures. While this is not complete melting, it represents a change in the material's physical state.

The insulating portion (130) may not be coated on top of the integrated circuit (IC) chip, and instead, a heat transfer portion (160) is provided at the top. The heat transfer portion (160) connects to the heat dissipation portion (170) using a silicon pad as TIM (Thermal Interface Material). This structure greatly improves the package's thermal management capability. By effectively transferring and releasing heat generated from high-performance chips to the heat dissipation portion (170), it improves system stability and performance.

The UV-curable molding material of the insulating portion (130) preferably has a low dielectric constant (typically 3.0 to 4.0) and low dielectric loss factor (typically 0.01-0.03). This plays an important role in maintaining high-frequency signal integrity. These characteristics are particularly important in high-frequency applications such as 5G.

After curing, the insulating portion (130) has high hardness (Shore D hardness 70˜90) and excellent impact resistance. This plays an important role in protecting internal electronic devices from external impacts. Additionally, the coefficient of thermal expansion (CTE) is adjusted to be similar to that of the substrate and chip to minimize deformation due to thermal stress.

Furthermore, the UV-curable molding material of the insulating portion (130) has excellent moisture resistance and heat resistance. It guarantees moisture resistance reliability for over 1000 hours under 85° C./85% RH conditions and maintains stable performance in a temperature range from −40° C. to 125° C.

Meanwhile, in this embodiment, the insulating portion can be either conformal or non-conformal.

The non-conformal case is when it is not uniformly coated following the external shape of the first package (210) and second package (220).

The conformal case refers to when it is uniformly coated following the external shape of the first package and second package. Conformal insulating portions can form insulating portions of uniform thickness even on complex 3D structured surfaces, and since it is coated following the fine structures and shapes of electronic components, it can maintain gaps between components and fine structures, making it very advantageous for high-density packaging. Additionally, since liquid molding material is evenly applied to all surfaces, it can minimize the occurrence of voids or bubbles that might occur in conventional molding methods.

For conformal coating, the coating material's viscosity is preferably 50-500 cPs (based on 25° C.). Exceeding this range makes spraying difficult, and if too low, excessive flow makes uniform coating difficult.

During coating, the spray nozzle pressure is preferably 10-60 psi (69-414 kPa). Below this range results in insufficient coverage, and exceeding this range risks overspray or droplet formation.

The electromagnetic shielding layer (140) plays an important role in protecting internal electronic components from electromagnetic interference (EMI), is formed on the insulating portion, and is applied using conformal coating technology.

The shielding layer preferably has shielding performance of over 60 dB, maintains surface resistance below 30 mΩ/sq to secure high electrical conductivity, and satisfies ASTM D3359 standard 5B or higher for adhesion between the shielding layer and insulation layer to prevent coating delamination.

The thickness of the shielding layer is controlled within 5˜30 μm range, which provides effective EMI shielding performance while minimizing the overall package thickness.

The shielding layer (140) material primarily uses conductive ink or paste containing metal particles (e.g., silver, copper, nickel). This material has excellent electrical conductivity and can effectively block electromagnetic waves and magnetic fields. After coating, it undergoes thermal curing at 120° C. for 1 hour. This thermal curing process serves to increase the mechanical strength of the shielding layer and stabilize its electrical characteristics.

The shielding layer (140) of this invention provides bi-directional shielding functionality that not only blocks external electromagnetic waves but also prevents electromagnetic waves generated inside the package from being emitted externally. This greatly improves the performance and reliability of SiP packages in high-frequency operating environments.

Another important characteristic of the shielding layer is that it can be electrically connected to the substrate's ground pad (150). For this purpose, selective coating is performed when forming the shielding layer to connect with the ground pad (150) of the substrate, allowing the shielding layer material to directly contact this ground pad. This ground connection maximizes the shielding effect and also improves electrostatic discharge (ESD) protection functionality.

For forming the electromagnetic shielding layer, spray coating or dispensing methods can be used. Both methods have the advantage of being able to form uniform and continuous shielding layers on complex 3D structured SiP package surfaces. Particularly, the spray coating method enables quick and uniform coating over large areas, while the dispensing method is useful when precise pattern formation is needed.

To achieve conformal coating characteristics when forming the electromagnetic shielding layer (140), the spray nozzle pressure is maintained at 10˜60 psi to ensure uniform spraying of fine particles, the distance between nozzle and substrate is set at 1˜15 mm to form appropriate spray patterns, and the spray angle is maintained at 70˜110 degrees relative to the substrate to obtain uniform coating thickness.

The spray gun movement speed is controlled at 10˜500 mm/s to achieve desired thickness, and the coating material viscosity is preferably maintained at 200˜400 cPs to secure appropriate flow and coverage. Perfect shielding layers without pinholes or discontinuities can be formed using multiple pass coating techniques.

Through such precise process control, this invention's electromagnetic shielding layer (140) can uniformly cover all surfaces of the SiP package while selectively connecting to desired parts (e.g., ground pads).

Also, to prevent cracking or delamination that might occur during thermal curing, it is preferable to slowly control the temperature rise rate to 2˜3° C./min up to the curing temperature, with the cooling process proceeding at a similar rate.

The dam means (180) is a means provided to prevent overflow of the insulating portion onto the ground electrode during the insulating portion coating process. If the insulating portion flows to the ground electrode, the ground electrode becomes insulated, significantly reducing the shielding function of the electromagnetic shielding layer, thus preventing this.

In the third embodiment, the dam means (180) can be provided in the form of forming an electrically conductive dam as in the first embodiment. The dam means (180) is provided on the position where the ground pad (150) is formed on the substrate with electronic devices to be electrically connected with the ground pad (150), simultaneously blocking the flow of the insulating portion (130) coating liquid and achieving electrical connection with the electromagnetic shielding layer.

Also, it will be apparent to those skilled in the art that in the third embodiment, the dam means (180) can be provided in the form of forming an insulating dam as in the second embodiment. Therefore, descriptions overlapping with the first and second embodiments are omitted.

### Seventh Embodiment

The semiconductor package of the seventh embodiment of this invention includes a substrate (110), electronic devices including first package (210) and second package (220), insulating portion (130), electromagnetic shielding layer (140), heat transfer layer (160), heat dissipation portion (170), and dam means (180). FIG. 7 shows a cross-sectional view of this embodiment. Accordingly, the board-level semiconductor package according to this embodiment differs from the second embodiment in that it is board level, and differs from the first embodiment in that it includes POP structured semiconductor electronic devices.

In this embodiment, both the insulating portion (130) and electromagnetic shielding layer (140) are formed by conformal coating, where the insulating portion (130) is 10˜200 μm, and the insulating portion (130) becomes flexible under specific conditions to be reworkable. At this time, spray or jetting methods or dispensing methods are used for coating.

Additionally, the insulating portion (130) does not cover the ground pad (150), and the electromagnetic shielding layer (140) is electrically connected to the ground pad (150).

In this embodiment, since the descriptions of the insulating portion, electromagnetic shielding layer, heat transfer layer, heat dissipation portion, and dam means are identical to the previously described embodiments, detailed explanations are omitted.

### Eighth Embodiment

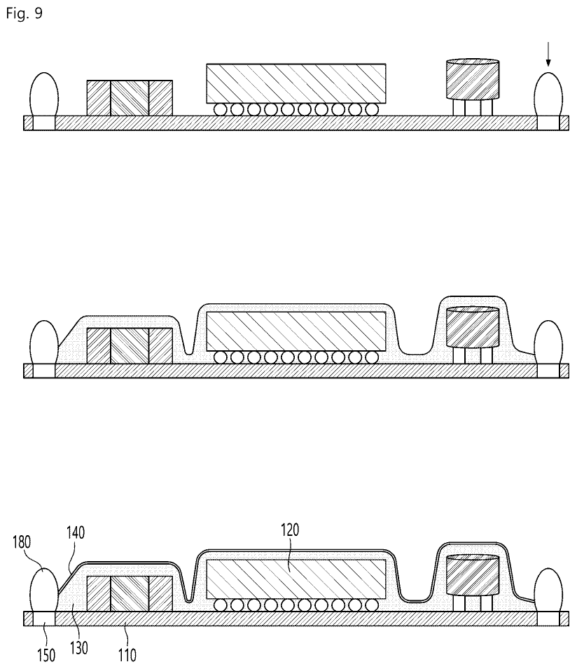

The eighth embodiment of this invention includes dam means (180). The dam means of this embodiment can use conductive paste or conductive ink, and in this case, the dam means is formed by applying through dispensing or jetting processes. The eighth embodiment will be described later with reference to FIG. 9, which is the second embodiment of the manufacturing method.

### Second Aspect: Manufacturing Method of Semiconductor Package

The manufacturing method of the semiconductor package according to this invention includes dam means formation step, insulating portion formation step, and shielding layer formation step.

### First Embodiment

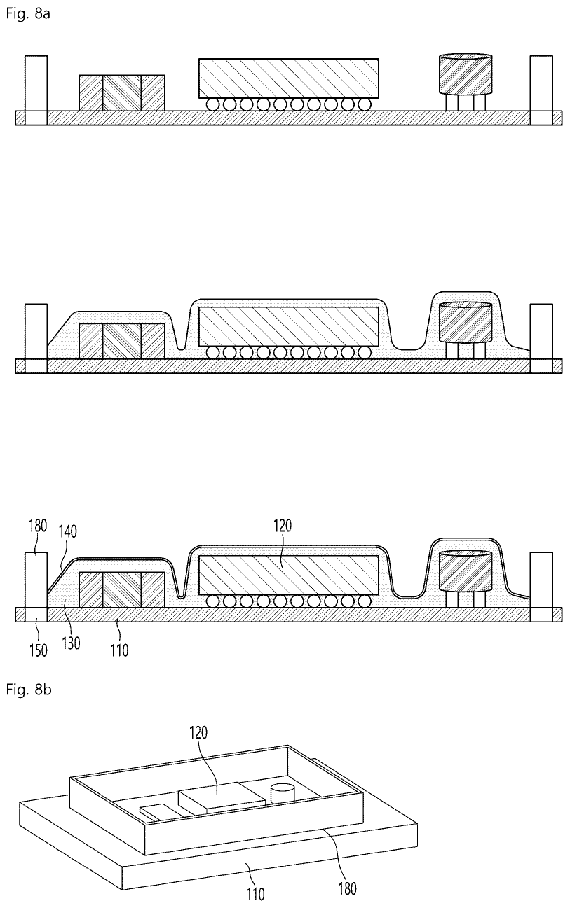

FIG. 8a shows a cross-sectional view illustrating the first embodiment of the manufacturing method of the semiconductor package according to this invention.

The dam means formation step is a step of forming means to prevent the flow of the insulating portion coating liquid. The dam means is formed around the ground pad on a substrate having electronic devices mounted and having ground pads located near the edges. In this embodiment, the dam means is physically installed using solid metal. FIG. 8b shows a perspective view illustrating the dam means of the semiconductor package according to this invention.

The height of the dam means is determined considering the thickness of the insulating portion to be formed in subsequent processes. Generally, it is preferable to set it within a range of 80% to 200% of the insulating portion thickness. This is to effectively block the flow of the insulating portion coating liquid while ensuring electrical contact with the shielding layer. At this time, the dam means formed in this embodiment has electrical continuity with the ground pad.

The insulating portion formation step is a step of coating insulating material over the substrate and electronic components. The insulating portion formation step must have excellent insulation characteristics, heat resistance, and low moisture absorption. The material viscosity is controlled at 50-500 cPs (based on 25° C.) to enable uniform coating while preventing excessive flow, and even if the insulating material has flowability after application in the insulating portion formation step, its flow is limited by the dam means and does not overflow to cover the ground pad.

The coating uses spray coating or jetting equipment, and the spray nozzle pressure is set in the range of 20-40 psi (138-276 kPa) to ensure uniform spraying of fine particles. The distance between nozzle and substrate, spray angle, etc., are optimized to achieve uniform coating thickness.

The prepared insulating material is coated over the entire substrate with mounted electronic devices. During this process, the previously formed dam means controls the flow of insulating material to prevent covering the ground pad. Coating is performed in multiple thin layers to minimize bubble formation and ensure uniform thickness.

The coated insulating material is cured using UV or heat. UV energy of 3000 to 10000 mJ is irradiated to ensure complete curing. UV curing provides advantages of faster curing speed and lower thermal stress compared to thermal curing.

After curing is completed, surface cleaning or plasma treatment can be performed as needed to optimize the surface condition for the subsequent shielding layer formation process.

For conformal coating, the coating material's viscosity is preferably 50-500 cPs (based on 25° C.). Exceeding this range makes spraying difficult, and if too low, excessive flow makes uniform coating difficult.

As needed, the insulating portion may be selectively not formed in some sections. This can be performed for RF performance optimization or thermal management of specific areas.

The insulating portion formed through this process serves to physically and electrically protect the electronic devices inside the semiconductor package. Additionally, this insulating portion has characteristics that allow rework by becoming flexible under specific conditions, which can be useful when package repair or rework is needed.

The shielding layer formation step is a step for protecting the electronic components inside the package from electromagnetic interference (EMI). The shielding layer is formed on the insulating portion and also on the electrode pad. First, prepare the conductive material to be used for shielding layer formation. This material is primarily conductive ink or paste containing metal particles such as silver, copper, nickel. The material viscosity is maintained at 200˜400 cPs to secure appropriate flow and coverage. The selected material must have excellent electrical conductivity to effectively block electromagnetic waves and magnetic fields.

Next, set up spray coating or dispensing equipment. The spray nozzle pressure is maintained at 30 to 50 psi to ensure uniform spraying of fine particles. The distance between nozzle and substrate is set at 20 to 25 cm, and spray angle is maintained at 60 to 80 degrees relative to the substrate to obtain uniform coating thickness. The spray gun movement speed is controlled at 15 to 30 cm/s to achieve desired thickness.

Before coating, clean the insulating portion surface and perform plasma treatment or primer application as needed to improve shielding layer adhesion. Then coat the prepared conductive material over the entire substrate with formed insulating portion. During this process, ensure the shielding layer is electrically connected to the metal dam means.

Next, cure the coated shielding layer in a thermal curing oven. At this time, to prevent cracking or delamination, slowly control the temperature rise rate to 2˜3° C./min up to the curing temperature, with the cooling process proceeding at a similar rate. The thermal curing process serves to increase the mechanical strength of the shielding layer and stabilize its electrical characteristics.

As needed, parts of the shielding layer may be selectively not formed. This can be performed for RF performance optimization or thermal management of specific areas.

The thickness of the shielding layer (140) is controlled within 5˜30 μm, more preferably 5 to 20 μm range, which provides effective EMI shielding performance while minimizing the overall package thickness.

The shielding layer preferably has shielding performance of over 60 dB, maintains surface resistance below 30 mΩ/sq to secure high electrical conductivity, and satisfies ASTM D3359 standard 5B or higher for adhesion between the shielding layer and insulation layer to prevent coating delamination.

Additionally, inspect the electrical continuity between the shielding layer and ground pad to confirm that the shielding layer is properly connected to the ground pad through the dam means.

### Second Embodiment

FIG. 9 shows a process diagram explaining the second embodiment of the manufacturing method of this invention. Descriptions identical to the first embodiment are omitted below.

The dam means formation step is a step of forming means to prevent the flow of the insulating portion coating liquid. The dam means is formed on the ground pad on a substrate having electronic devices mounted and having ground pads located near the edges. In this embodiment, the dam means can use conductive paste or conductive ink.

In this case, the dam means is formed by applying through dispensing or jetting processes. Then, sufficient curing is performed at 120° C.˜150° C. for 30˜120 minutes. The dam means prevents insulating paste from invading the ground electrode or scattering outside the coating range and serves as a connection between the shielding layer and ground electrode.

The dam means is preferably formed with a width of 300˜500 μm and a height of 300˜700 μm.

When using the dispensing method, continuously apply conductive material around the ground pad through a precise nozzle. When using the screen printing method, apply conductive material through a screen with pre-designed pattern. The material to be dispensed must maintain appropriate viscosity while having high electrical conductivity to maintain its shape.

When using dispensing or screen printing methods, undergo a curing process after dam means formation. The curing method can be selectively applied as room temperature curing, thermal curing, or UV curing depending on the material used.

The insulating portion formation step is a step of coating insulating material over the substrate and electronic components. The insulating portion formation step must have excellent insulation characteristics, heat resistance, and low moisture absorption. The material viscosity is controlled at 50-500 cPs (based on 25° C.) to enable uniform coating while preventing excessive flow.

In the insulating portion formation step, even if the insulating material has flowability after application, its flow is limited by the dam means and does not overflow to cover the ground pad.

The insulating portion is uniformly applied to the entire substrate and electronic components through spray method, and the thickness of the applied insulating portion is set in the range of 10˜200 μm. This thickness is a designed value that can satisfy both electrical insulation and physical protection.

The insulating portion material uses thermal curing materials (for example, thermosetting epoxy) or UV curing materials (for example, UV-curable acrylate). Thermosetting epoxy provides high heat resistance and strength with excellent electrical stability characteristics, while UV acrylate provides fast curing speed and excellent re-workability advantages. The Breakdown Voltage of the insulating portion meets the insulation requirements of PCB (Printed Circuit Board) and is designed to withstand voltage stress.

While thermal curing materials have re-workability limited to about 50%, they provide high mechanical strength and durability, and the UV curing material's insulating portion allows 100% re-workability, making package repair or rework easy when needed. Curing using UV energy achieves fast and effective curing by irradiating 3000˜10000 mJ/cm².

The shielding layer formation step is a step for protecting the electronic components inside the package from electromagnetic interference (EMI). The shielding layer is formed on the insulating portion and also on the electrode pad. First, prepare the conductive material to be used for shielding layer formation. This material is primarily conductive ink or paste containing metal particles such as silver, copper, nickel. The material viscosity is maintained at 200˜400 cPs to secure appropriate flow and coverage.

The shielding material is applied using Spray method or Inkjet method to a thickness of 5˜30 μm on the substrate and insulation layer, and this thickness is a designed range that can simultaneously satisfy shielding effect and physical strength.

The shielding layer (140) material primarily uses conductive paste or ink containing metal particles (e.g., silver, copper, nickel). This material has excellent electrical conductivity and can effectively block electromagnetic waves and magnetic fields. After coating, it undergoes thermal curing at 120° C.˜150° C. for 30˜120 minutes. This thermal curing process serves to increase the mechanical strength of the shielding layer and stabilize its electrical characteristics.

The shielding layer preferably has shielding performance of over 60 dB, maintains surface resistance below 30 mΩ/sq to secure high electrical conductivity, and satisfies ASTM D3359 standard 5B or higher for adhesion between the shielding layer and insulation layer to prevent coating delamination.

The shielding layer is connected to the dam means and electrically connected to the ground electrode. The conductive dam is formed higher than the insulating layer thickness, naturally creating electrical connection after shielding layer coating. This ground connection improves electromagnetic shielding efficiency while also enhancing magnetic field and electrostatic discharge (ESD) protection functionality.

### Third Embodiment

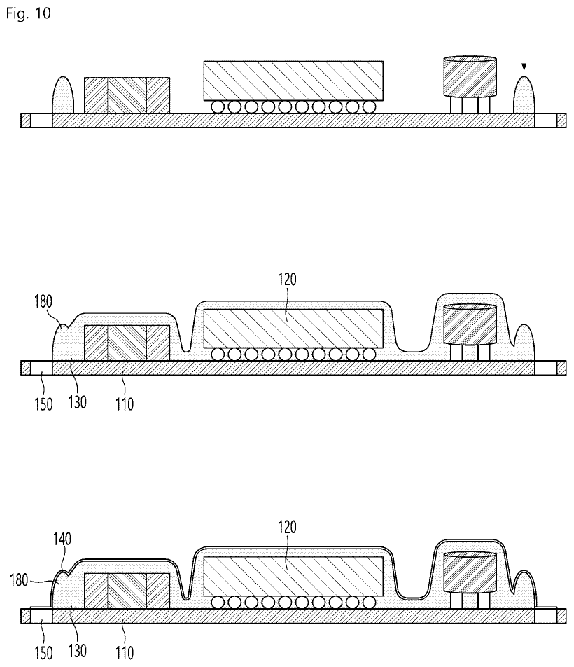

FIG. 10 shows a cross-sectional view illustrating the third embodiment of the manufacturing method of the semiconductor package according to this invention. Descriptions identical to the first embodiment are omitted below.

The dam means formation step is a step of forming means to prevent the flow of the insulating portion coating liquid. The dam means is formed around the ground pad on a substrate having electronic devices mounted and having ground pads located near the edges. In this embodiment, insulating material can be used for the dam means. In this case, dispensing method or screen printing method can be used as the formation method for the dam means.

The insulating portion formation step is a step of coating insulating material over the substrate and electronic components. The insulating portion formation step must have excellent insulation characteristics, heat resistance, and low moisture absorption. The material viscosity is controlled at 50-500 cPs (based on 25° C.) to enable uniform coating while preventing excessive flow.

In the insulating portion formation step, even if the insulating material has flowability after application, its flow is limited by the dam means and does not overflow to cover the ground pad.

The shielding layer formation step is a step for protecting the electronic components inside the package from electromagnetic interference (EMI). First, prepare the conductive material to be used for shielding layer formation. This material is primarily conductive ink or paste containing metal particles such as silver, copper, nickel. The material viscosity is maintained at 200˜400 cPs to secure appropriate flow and coverage.

In this embodiment, the shielding layer is coated on the external surface of the insulating portion including the external surface of the dam means, and the end portion is also connected to the ground pad.

### Experimental Example

Table 1 below summarizes the results of measuring weight reduction effect, thickness reduction effect, board area occupancy, and thermal conductivity compared to conventional shield can after SMT process for selective area conformal coating and reworkable EMI shielding coating of this invention.

TABLE 1

| | | Invention: Conformal |
|---|---|---|
| | Shield Can | EMI Shielding Coating |
| Weight | 1 g (200~300 μm | 0.2~0.3 g (50~100 μm |
| | SUS, Copper) | Polymer + 5~10 μm |
| | | Ag Coating) |
| Thickness | 0.2~0.3 mm + | 0.05~0.1 mm |
| | Gap (Air Gap) | |
| PCB Area | High (Surrounding the | Low (Only Partial |
| Utilization | Cover Edges) | Adhered Area) |
| Thermal | Poor (Due to Air Gaps) | Good (No Air Gaps) |
| Conductivity | | |

Weight was reduced by 70˜80% compared to existing shield can, and thickness measurement confirmed a reduction of 0.1˜0.2 mm compared to existing shield can.

These features of the present invention provide significant advantages especially in products where weight reduction and slimming are important, such as mobile devices or wearable devices.

The features, structures, effects, etc. exemplified in each embodiment described above can be combined or modified for implementation with other embodiments by those skilled in the art to which the embodiments belong. Therefore, such combinations and modifications should be interpreted as being included within the scope of this invention.

Description of Reference Numerals

| | |
|---|---|
| 110 | Substrate |
| 120 | Electronic Device |
| 130 | Insulating Portion |
| 140 | Shielding Layer |
| 150 | Ground Pad |
| 160 | Heat Transfer Layer |
| 170 | Heat Dissipation Portion |
| 210 | First Package |
| 220 | Second Package |

What is claimed is:

1. A semiconductor package comprising:
a substrate;
a ground pad formed on the substrate;
at least one electronic device electrically connected to the substrate;
an insulating portion encapsulating the electronic device; and
an electromagnetic shielding layer conformally formed along a surface of the insulating portion and electrically connected to the ground pad.

2. The semiconductor package of claim 1, further comprising:
a conductive dam portion formed on the ground pad,
wherein the insulating portion and the electromagnetic shielding layer are electrically connected by contacting the dam portion.

3. The semiconductor package of claim 1, further comprising:
an insulating dam portion formed on an edge of the substrate,
wherein the electromagnetic shielding layer is electrically connected by being formed on the insulating portion, the dam portion, and the ground pad.

4. The semiconductor package of claim 1, wherein the insulating portion is reworkable.

5. The semiconductor package of claim 1, wherein the insulating portion is formed of a UV-curable polymer material.

6. The semiconductor package of claim 1, wherein the insulating portion has a thickness ranging from 10 μm to 200 μm.

7. The semiconductor package of claim 1, wherein the insulating portion is formed by a conformal coating method.

8. The semiconductor package of claim 7, wherein the conformal coating is performed using a material having a viscosity of 50-500 cPs at 25° C.

9. The semiconductor package of claim 1, wherein the electromagnetic shielding layer has a thickness ranging from 5 μm to 30 μm.

10. The semiconductor package of claim 1, wherein the electromagnetic shielding layer is formed of a conductive ink or paste containing metal particles.

11. The semiconductor package of claim 1, wherein:
the electronic device comprises multiple integrated circuit chips, and
the multiple integrated circuit chips are horizontally arranged on the single substrate.

12. The semiconductor package of claim 11, further comprising a vapor chamber formed on top of the insulating portion.

13. The semiconductor package of claim 1, wherein the electronic device comprises:
a first package being a lower package containing a chip; and
a second package being an upper package containing a chip and stacked on the first package.

14. The semiconductor package of claim 13, wherein the insulating portion is formed on external surfaces of the first package and the second package.

15. The semiconductor package of claim 13, further comprising:
a heat transfer layer formed on an exposed top surface of the second package.

16. The semiconductor package of claim 15, further comprising:
a heat dissipation portion formed on top of the heat transfer layer.

17. A method of manufacturing a semiconductor package, comprising:
forming a dam portion on an edge of a substrate having electronic devices mounted thereon and including a ground pad;
forming an insulating portion covering the dam portion and the electronic devices while exposing the ground pad; and
forming an electromagnetic shielding layer on the insulating portion.

18. The method of claim 17, wherein:
the dam portion comprises a solid conductive material, and
the electromagnetic shielding layer is electrically connected by contacting the dam portion.

19. The method of claim 17, wherein:
the dam portion comprises a conductive paste or conductive ink, and
the electromagnetic shielding layer is electrically connected by contacting the dam portion.

20. The method of claim 17, wherein forming the dam portion comprises using a dispensing method or a screen printing method.

21. The method of claim 17, wherein:
the dam portion comprises an insulating material, and
the electromagnetic shielding layer covers an external surface of the dam portion and directly connects to the ground pad.

22. The method of claim 17, wherein a height of the dam portion is within a range of 80% to 200% of a thickness of the insulating portion.

23. The method of claim 17, wherein:
forming the insulating portion comprises using a spray coating or jetting method, and
performing UV curing or thermal curing after forming the insulating portion.

24. The method of claim 17, wherein forming the electromagnetic shielding layer comprises using a spray coating or jetting method.

25. The method of claim 17, further comprising:
including regions where the insulating portion or the electromagnetic shielding layer is selectively not formed.
